(19) United States
(12) Patent Application Publication
(10) Pub. No.: US 2018/0264752 A1
(43) Pub. Date: Sep. 20, 2018

(54) HOUSING AND METHOD OF FABRICATING THE HOUSING

(71) Applicant: Lenovo (Beijing) Co., Ltd., Beijing (CN)

(72) Inventors: Xiaoli FAN, Beijing (CN); Changlong ZUO, Beijing (CN)

(21) Appl. No.: 15/923,588

(22) Filed: Mar. 16, 2018

(30) Foreign Application Priority Data
Mar. 17, 2017 (CN) 201710161452.1

(51) Int. Cl. B29C 67/24; B29C 45/14; H05K 5/02

(52) U.S. Cl. CPC B29C 67/246; B29K 2705/00; H05K 5/0217; B29C 45/14065

(57) ABSTRACT

A housing includes one or more rigid portions and one or more flexible portions. The one or more rigid portions are formed by a foam metal. The one or more flexible portions are formed by a polymer elastomer and securely coupled to the one or more rigid portions.

### CROSS-REFERENCE TO RELATED APPLICATION

This application claims priority to Chinese Patent Application No. 201710161452.1, filed on Mar. 17, 2017, the entire contents of which are incorporated herein by reference.

### TECHNICAL FIELD

The present disclosure generally relates to the field of electronic device housing technologies and, more particularly, to an electronic device housing, a fabrication method thereof, and an electronic apparatus.

### BACKGROUND

In flexible electronic technology, organic/inorganic-materials electronic devices may be fabricated on flexible/ductile plastics or thin metal substrates. Due to flexibility/ductility and efficient and low-cost fabrication processes, electronic devices fabricated using flexible electronic technology have broad application prospects in information, energy, and medical, defense and other fields, e.g., flexible electronic displays, organic light-emitting diodes (OLED), printed radio frequency identification (RFID), thin film solar panels, skin patches, etc.

Due to flexible and bending properties of flexible electronic devices, a housing of the flexible electronic device may need to include some preset regions that are rigid and inelastic and some other regions that are soft and elastic.

In a method of metal insert molding, i.e., metal insert injection molding, thermoplastic elastomers may be coupled to high rigidity plates by injection molding. However, because the contact areas between the thermoplastic elastomers and the high rigidity plates are small, it may be easy for seams to break apart.

In a method of combining thermoplastic elastomers and a metal plate by a nano molding technology (NMT) process, after the surface of the metal substrate, i.e., the surface of the metal plate, is treated, plastics are directly injection molded over the metal surface, such that the metal and plastics are integrally formed, i.e., integrated. However, in the housing fabricated by the nano molding technology (NMT) process, elastomers may be deformed by force and break away from micro-nano pores, causing elastomers to separate from the metal plate.

### SUMMARY

In one aspect, the present disclosure provides a housing including one or more rigid portions and one or more flexible portions. The one or more rigid portions are formed by a foam metal. The one or more flexible portions are formed by a polymer elastomer and securely coupled to the one or more rigid portions.

### BRIEF DESCRIPTION OF THE FIGURES

The following drawings are merely examples for illustrative purposes according to various disclosed embodiments and are not intended to limit the scope of the present disclosure.

FIG. 1 shows a low magnification image of an example of foam metal prepared by an example of electrochemical deposition sintering method consistent with various disclosed embodiments of the present disclosure;

FIG. 2 shows a high magnification image of an example of foam metal prepared by an example of electrochemical deposition sintering method consistent with various disclosed embodiments of the present disclosure;

FIG. 3 illustrates an overall view of an example of foam metal prepared by an example of electrochemical deposition sintering method consistent with various disclosed embodiments of the present disclosure;

FIG. 4 illustrates a schematic view of an example of foam metal prepared by an example of 3-dimensional (3D) printing method consistent with various disclosed embodiments of the present disclosure;

FIG. 5 illustrates a local zoom-in view of an example of foam metal prepared by an example of 3D printing method consistent with various disclosed embodiments of the present disclosure;

FIG. 6 illustrates a schematic view of examples of rigid portions formed by foam metals consistent with various disclosed embodiments of the present disclosure;

FIG. 7 illustrates a schematic view of an example of housing after polymer elastomers are filled consistent with various disclosed embodiments of the present disclosure; and

FIG. 8 illustrates a schematic view of an example of housing with polymer elastomers in a bent state consistent with various disclosed embodiments of the present disclosure.

### DETAILED DESCRIPTION

Some embodiments of the disclosure will now be described in more detail with reference to the drawings. It is to be noted that, the following descriptions of some embodiments are presented herein for purposes of illustration and description only, and are not intended to be exhaustive or to limit the scope of the present disclosure.

The aspects and features of the present disclosure can be understood by those skilled in the art through the example embodiments of the present disclosure further described in detail with reference to the accompanying drawings.

The present disclosure provides an electronic device housing, also referred to as an “electronic device case,” that includes one or more hard portions and one or more soft portions. Hereinafter, an electronic device housing including hard and soft portions is also referred to as a “soft-hard electronic device housing” and a housing including hard and soft portions is also referred to as a “soft-hard housing.”

The soft-hard electronic device housing may include one or more rigid portions formed by foam metals and one or more flexible portions formed by polymer elastomers. The one or more flexible portions may be securely coupled to the one or more rigid portions.

The electronic device housing of the disclosure may include foam metals to form a rigid skeleton with an excellent rigidity.

In the present disclosure, the metal type of the foam metals is not restricted, and may be selected according to various application scenarios. For example, the foam metals can include a high rigidity metal.

In the present disclosure, the method for fabricating the foam metals is not restricted, and may be selected according to various application scenarios. For example, the foam metals can be fabricated using a powder metallurgy method, an electroplating method, or a 3-dimensional (3D) printing method.

The electronic device housing of the disclosure may have applications in electronic devices including but not limited to: smart phones, watches, smart glasses, tablet computers, laptop computers, etc.

In some embodiments, the foam metals may have pore diameters ranging from approximately 0.05 mm to approximately 1.0 mm. In some other embodiments, the foam metals may have pore diameters ranging from approximately 0.1 mm to approximately 0.3 mm. The housing formed by the foam metals having pore diameters, for example, in the above-mentioned range can have a good mechanical property and a uniform appearance.

In some embodiments, a porosity of the foam metals may range from approximately 40% to approximately 90%. A foam metal having a porosity, for example, in the above-mentioned porosity range can meet housing process needs on a strength, a modulus, and an injection moldability.

In the present disclosure, the polymer elastomers may be securely coupled to the above-described foam metals to form the soft-hard electronic device housing that can be bent.

In the present disclosure, a material of the polymer elastomers is not restricted, and may be selected according to various application scenarios. The material of the polymer elastomers may include, for example, a thermosetting elastomer such as a rubber, or a thermoplastic elastomer such as a polyurethane, a styrenic elastomer, a polyolefin elastomer, a polyamide elastomer, or the like.

In the present disclosure, the polymer elastomers may be securely coupled to the foam metals in such a manner that the polymer elastomers and the foam metals are interlaced and interconnected at junctions to form an interlaced network structure. A locking force caused by the interlacement between the polymer elastomers and the foam metals may result in a strong coupling between the foam metals and the polymer elastomers and hence the foam metals and the polymer elastomers may not easily disengage.

In some embodiments, the above-described interlaced coupling may include, for example, the polymer elastomers being filled in pores of the foam metals at junctions between the hard and soft portions, so as to form a network structure by interlacing, i.e., interpenetrating, the polymer elastomers and the foam metals at the junctions, and to provide a locking force to securely couple the one or more rigid portions and the one or more flexible portions. In some embodiments, another structure may be, for example, welded or fastened on foam metals that are not filled with polymer elastomers.

In some other embodiments, the polymer elastomers not only may fill pores of the foam metals at the junctions between the hard and soft portions, but also may fill pores of the foam metals at locations other than the junctions between the hard and soft portions according to various application scenarios. Accordingly, the housing may include a uniform elastomer to ensure a consistent appearance and a consistent feel.

In some embodiments, the foam metals and the polymer elastomers can be securely coupled to each other not only through the interlacement coupling, but also by adhesives at the junctions between the foam metals and the polymer elastomers, such that the foam metals and the polymer elastomers may have an improved coupling strength due to an interfacial adhesion, in addition to the locking force.

Besides being filled inside the pores of the foam metals to provide a secure coupling, the polymer elastomers can also be filled in one or more spacing regions between neighboring foam metals to form the one or more flexible portions, such that the housing may be flexible, i.e., bendable. Positions and shapes of the one or more flexible portions may be adjusted according to, for example, process needs such as a position of a housing portion that needs to be bendable, a shape of the housing, and an appearance of the housing. In the present disclosure, positions and shapes of the one or more flexible portions are not restricted and may be adjusted according to various application scenarios.

In some embodiments, the soft-hard electronic device housing may include at least two separate rigid portions formed by foam metals, and one or more flexible portions formed by polymer elastomers, where the number of the flexible portions may be smaller than the number of the rigid portions.

In some embodiments, the number of the flexible portions is smaller than the number of the rigid portions by one. Each of the flexible portions may be filled in a spacing region between each two separate rigid portions.

If the housing includes two rigid portions, the flexible portion may be filled in the spacing region between the two separate rigid portions and may be securely coupled to the rigid portions, such that the housing may be bendable. The secure coupling may include filling polymer elastomers in pores of foam metals, and interlacing the polymer elastomers and the foam metals.

If the housing includes more than two rigid portions, each flexible portion may be filled in a spacing region between each two separate rigid portions and may be securely coupled to the adjacent rigid portions, such that the housing may be flexible, i.e., bendable at a plurality of positions or may have a relatively large flexibility. The secure coupling may include a filling of the polymer elastomers in pores of the foam metals, and an interlacing between the polymer elastomers and the foam metals.

In some embodiments, the polymer elastomers may be filled in preset edge regions of the foam metals and spacing regions between neighboring foam metals, so as to form a flexible housing including soft and hard portions that has an appearance of an elastic body and a smooth feel.

The present disclosure provides a method for fabricating the above-described soft-hard electronic device housing. The method including fastening one or more rigid portions formed by foam metals in a mold and performing an injection molding by injecting polymer elastomers into the mold to form the electronic device housing.

The foam metals may be prepared by, for example, a powder metallurgy method, an electroplating method, or a 3D printing method.

The above-described injection molding may include, for example, a reaction injection molding or a liquid injection molding.

The foam metals may be precisely fastened in the mold, and the polymer elastomers may be filled into preset regions to perform injection molding according to flexibility needs of the housing, such that flexible soft-hard housing having a desired shape can be formed.

The present disclosure also provides an electronic apparatus comprising one of a housing consistent with the disclosure or a housing fabricated by a method consistent with the disclosure. The housing can be, for example, one of the above-described soft-hard electronic device housings or a soft-hard electronic device housing fabricated by the above-described fabrication method.

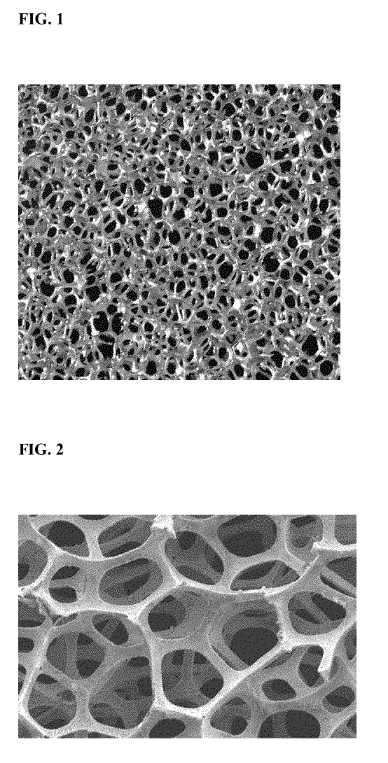

An example method for fabricating a three-dimensional reticulated foam metal, i.e., a three-dimensional reticulated foam metal insert, by electrochemical deposition sintering of a reticulated foam plastic is described below with reference to FIGS. 1-3.

1, prepare a polyurethane foam plastic. The polyurethane form plastic may include, for example, a polyester polyurethane foam plastic generally used in the field. In the present disclosure, raw materials and a method for preparing the polyurethane foam plastic are not restricted, and may be selected according to various application scenarios. For example, toluene diisocyanate, polyester polyol, water, organosilicon foam stabilizer, and other additives may be used as raw materials to prepare the polyurethane foam plastic.

2, perform a reticulation process by using alkali lye hydrolysis to remove bubble films.

3, cut a three-dimensional reticulated foam plastic into base foams having desired sizes, and preprocess the foams degrease the foams and remove residual pore walls in the foams.

4, apply a setting treatment on the foams, and a jig is used to ensure sizes and shapes of the forms.

5, perform a conductive treatment on the foams, e.g., chemical nickel-plating or conductive-graphite-adhesive dip coating.

6, perform an electroplating treatment to coat foam hole ridges with metal or metal alloy, such as a high rigidity metal, e.g., Cu or Ni. The metal or metal alloy may be only included in the hole ridges. The hole ridges may be interconnected with each other to form a frame structure. Pores may be in communication with each other. That is, the form may have a reticulation shape including through holes.

7, perform a reduction sintering, such that in a reducing atmosphere, a base polyurethane is pyrolyzed and the metal structure is sintered to be reinforced.

8, perform grinding and shape correction to ensure compliance with desired size and shape.

If adhesives are to be used between the polymer elastomer and the foam metal, the method may further include dip coating the adhesives after grinding and shape correction, so as to enhance an interfacial adhesion between the foam metal and the polymer elastomer.

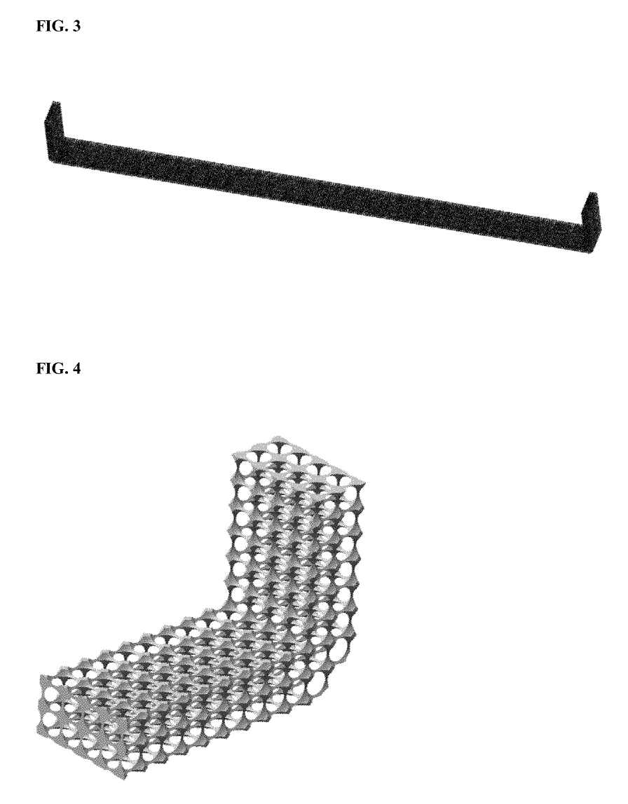

FIGS. 1 to 3 illustrate examples of prepared foam metals consistent with the disclosure. FIG. 1 shows a low magnification image of an example of foam metal prepared by an example of electrochemical deposition sintering method consistent with the disclosure. FIG. 2 shows a high magnification image of an example of foam metal prepared by an example of electrochemical deposition sintering method consistent with the disclosure. FIG. 3 illustrates an overall view of an example of foam metal prepared by an example of electrochemical deposition sintering method consistent with the disclosure.

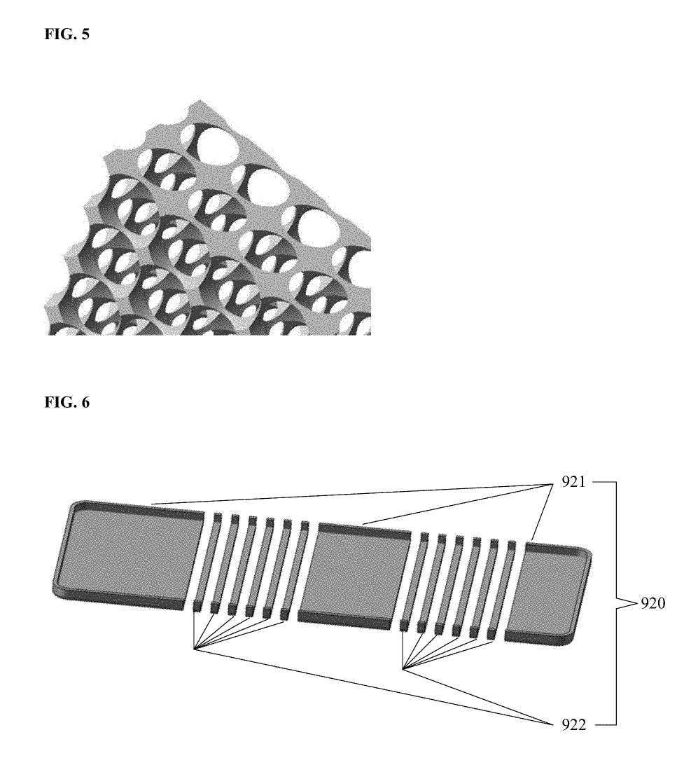

Another example method for preparing a three-dimensional reticulated foam metal insert by metal 3-dimensional (3D) printing is described below with reference to FIGS. 4 and 5.

1, perform computer modeling based on a data file of a 3D reticulation model.

2, perform 3D printing of stainless steel foam metal parts by, for example, selective laser sintering (SLS), selective laser melting (SLM), electron beam selective melting (EBSM), or another metal 3D printing process.

3, perform grinding and shape correction to ensure compliance with desired size and shape.

If adhesives are to be used between the polymer elastomer and the foam metal, the method may further include dip coating the adhesives after grinding and shape correction, so as to enhance an interfacial adhesion between the foam metal and the polymer elastomer.

The prepared foam metal is shown in FIGS. 4 and 5. FIG. 4 illustrates a schematic view of an example of foam metal prepared by an example of 3D printing method consistent with the disclosure. FIG. 5 illustrates a local zoom-in view of an example of foam metal prepared by an example of 3D printing method consistent with the disclosure.

An example method for fabricating a soft-hard housing including polyurethane elastomers by liquid injection molding is described below.

1, coat a mold release agent in a mold, and embed a foam metal into the mold. The foam metal may be accurately placed in position.

2, perform reaction injection molding to form polyurethane. For example, calculated amounts of component A (e.g. polyether, chain extender, catalyst, and other additives) and component B (isocyanate) are mixed by high pressure impact and injected into the mold. In the present disclosure, the raw materials of the polymer elastomer are not restricted and may be selected according to various application scenarios, e.g., a soft elastomer suitable for use in a housing.

3, perform curing, such that a gel reaction of liquid components A and B occurs in the mold to form a solid.

After the housing is formed, the method may further include post-treatment processes, e.g., shape correction, cleaning burrs, post-curing, to improve a strength and a heat resistance of the housing, etc., and testing and packaging processes to form a finished housing.

An example method for fabricating a soft-hard housing including rubber elastomers by liquid injection molding is described below.

1, coat a mold release agent in a mold, and embed a foam metal into the mold. The foam metal may be accurately placed in position.

2, perform injection molding to form two-component liquid silicone rubber. For example, calculated amounts of component A, e.g., polyorganosiloxane basic polymer containing vinyl+platinum catalyst, and component B, e.g., polyorganosiloxane basic polymer containing vinyl+polyorganosiloxane crosslinking agent containing Si—H bond, are mixed and injected into the mold through an injection molding machine. In the present disclosure, the raw materials of the rubber elastomer are not restricted and may be selected according to various application scenarios, e.g., a soft elastomer suitable for use in a housing.

3, perform vulcanization, such that a vulcanization reaction of liquid components A and B occurs in the high temperature mold to cross-link with each other and form a solid.

After the housing is formed, the method may further include post-treatment processes, e.g., shape correction, cleaning burrs, to improve a strength and a heat resistance of the housing, etc., and testing and packaging processes to form a finished housing.

FIGS. 6 to 8 shows an example prepared housing consistent with the disclosure. FIG. 6 is a schematic view of rigid portions 920 of the housing formed by foam metals. As shown in FIG. 6, the rigid portions 920 include rigid plate portions 921 and rigid strip portions 922. The rigid plate portions 921 include three portions spaced apart from each other, and are disposed in the head, tail, and intermediate regions of the housing, respectively. The rigid plate portions 921 and rigid strip portions 922 are arranged alternately. The rigid strip portions 922 include a plurality of foam metal strips arranged side-by-side. The plurality of foam metal strips are separated and arranged in parallel to each other. Further, the plurality of foam metal strips have extension directions perpendicular to a bending direction of the housing.

The housing may include a protective plate and a protective flap located at an edge of the protective plate.

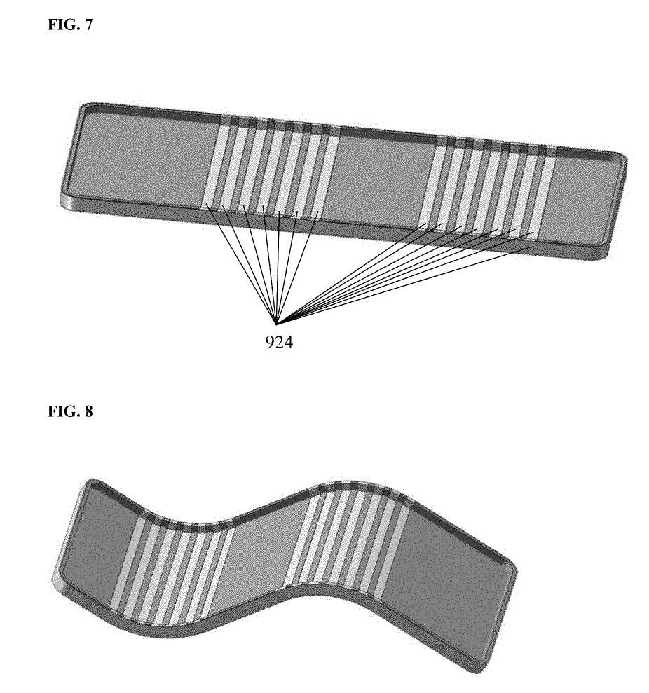

FIG. 7 is a schematic view of the housing after polymer elastomers 924 are filled in. As shown in FIG. 7, the polymer elastomers 924 are filled in pores of the foam metals and spacing regions between neighboring foam metals. That is, polymer elastomers are filled in gaps between the rigid plate portions and the rigid strip portions and in gaps between the plurality of foam metal strips of the rigid strip portions. Further, an outer side of the housing can also be covered with the elastomers 924.

FIG. 8 is a schematic view of the housing with polymer elastomers in a bent state.

For example, as shown in FIG. 8, the housing can be bent in an S-shape.

In the housing fabricated by the fabrication method of the disclosure, some regions may be rigid and inelastic, and some other regions may be soft and elastic and may be bent. Further, the hard and soft regions are securely bonded to each other.

The present disclosure provides an electronic device housing including one or more hard regions and one or more soft regions, a fabrication method thereof, and an electronic apparatus including the housing.

The present disclosure provides an electronic device housing having soft and hard portions. The housing may include one or more rigid portions formed by foam metals and one or more flexible portions formed by polymer elastomers. The foam metals and the polymer elastomers may be securely coupled to each other. The electronic device housing of the disclosure may include the foam metals to provide a rigid skeleton with rigidity. Further, secure coupling may be achieved by using polymer elastomers and foam metals. A locking force caused by the interlacement between the polymer elastomers and the foam metals may make the coupling between the foam metals and the polymer elastomers strong and not easy to disengage. Further, a housing exterior may include a uniform elastomer to ensure a consistent appearance and a consistent feel.

The foregoing description of the embodiments of the disclosure has been presented for purposes of illustration and description. It is not intended to be exhaustive or to limit the disclosure to the precise form or to example embodiments disclosed. Accordingly, the foregoing description should be regarded as illustrative rather than restrictive. Obviously, many modifications and variations will be apparent to persons skilled in this art. The embodiments are chosen and described in order to explain the principles of the technology, with various modifications suitable to the particular use or implementation contemplated. It is intended that the scope of the invention be defined by the claims appended hereto in which all terms are meant in their broadest reasonable sense unless otherwise indicated. Therefore, the term “the disclosure,” “the present disclosure,” or the like does not necessarily limit the claim scope to a specific embodiment, and the reference to example embodiments of the disclosure does not imply a limitation on the invention, and no such limitation is to be inferred. Moreover, the claims may refer to “first,” “second,” etc., followed by a noun or element. Such terms should be understood as a nomenclature and should not be construed as giving the limitation on the number of the elements modified by such nomenclature unless specific number has been given. Any advantages and benefits described may or may not apply to all embodiments of the disclosure. It should be appreciated that variations may be made to the embodiments described by persons skilled in the art without departing from the scope of the present disclosure. Moreover, no element or component in the present disclosure is intended to be dedicated to the public regardless of whether the element or component is explicitly recited in the following claims.

What is claimed is:

1. A housing comprising:
one or more rigid portions formed by a foam metal; and
one or more flexible portions formed by a polymer elastomer and securely coupled to the one or more rigid portions.

2. The housing according to claim 1, wherein:
the foam metal and the polymer elastomer are interlaced with each other at one or more junctions between the one or more rigid portions and the one or more flexible portions.

3. The housing according to claim 2, further comprising:
an adhesive applied at the one or more junctions between the one or more rigid portions and the one or more flexible portions.

4. The housing according to claim 1, wherein:
a portion of the polymer elastomer is filled in pores of the foam metal.

5. The housing according to claim 1, wherein:
the one or more rigid portions include at least two separate rigid portions formed by the foam metal, and
the number of the one or more flexible portions is smaller than the number of the one or more rigid portions by one.

6. The housing according to claim 5, wherein:
the polymer elastomer is filled in pores of the foam metal and spacing regions between neighboring rigid portions formed of the foam metal.

7. The housing according to claim 6, wherein:
the polymer elastomer filled in the pores of the foam metal interlace with the foam metal.

8. The housing according to claim 6, wherein:
the polymer elastomer is further filled in an edge region of the one or more rigid portions.

9. The housing according to claim 1, wherein:
pore diameters of the foam metal range from approximately 0.05 mm to approximately 1.0 mm.

10. The housing according to claim 1, wherein:
a porosity of the foam metal ranges from approximately 40% to approximately 90%.

11. An electronic apparatus comprising the housing according to claim 1.

12. A method for fabricating the housing according to claim 1, comprising:
fastening the one or more rigid portions in a mold; and
performing injection molding by injecting the polymer elastomer into the mold to form the housing.

13. The method according to claim 12, further comprising:
preparing the one or more rigid portions by a powder metallurgy method, an electroplating method, or a 3-dimensional printing method.

14. The method according to claim 12, wherein performing the injection molding includes:
performing a reaction injection molding or a liquid injection molding.

15. An electronic apparatus comprising a housing fabricated by the method according to claim 12.
